(19) United States
(12) Patent Application Publication
(10) Pub. No.: US 2024/0282527 A1
(43) Pub. Date: Aug. 22, 2024

(54) CAPACITOR, IN PARTICULAR DC LINK CAPACITOR FOR A MULTI-PHASE SYSTEM

(71) Applicant: Robert Bosch GmbH, Stuttgart (DE)

(72) Inventor: Johannes Ruthardt, Stuttgart (DE)

(21) Appl. No.: 18/443,294

(22) Filed: Feb. 16, 2024

(30) Foreign Application Priority Data
Feb. 17, 2023 (DE) 10 2023 201 394.0

(51) Int. Cl. H01G 4/228; H01G 4/38; H05K 7/20

(52) U.S. Cl. CPC H01G 4/228; H01G 4/385; H05K 7/209

(57) ABSTRACT

A capacitor including a surface electrode and a further surface electrode. A first capacitor structure is arranged between a first region of the surface electrode and a further first region of the further surface electrode. The first capacitor structure is electrically connected to the first region of the surface electrode and to the further first region of the further surface electrode. The first region of the surface electrode is arranged on a base side of the capacitor. The further first region of the further surface electrode is arranged on an upper side of the capacitor facing away from the base side. A second capacitor structure is arranged between a second region of the surface electrode and a further second region of the further surface electrode. The second capacitor structure is electrically connected to the second region of the surface electrode and the further second region of the further surface electrode.

### BACKGROUND

The invention relates to a capacitor, in particular an DC link capacitor for a multi-phase system. The invention further relates to an assembly comprising the capacitor.

In power electronics, a plurality of electrical networks are energetically coupled at a common DC voltage level via electrical capacitors in an DC link of converters. The repeated occurrence of switching operations results in frequency-dependent high power losses due to the alternating currents of the phases. In order to maximize the service life of capacitors in power electronics, heat generated in capacitors must be minimized and efficiently dissipated to a heat sink.

### SUMMARY

Proposed according to the invention is a capacitor, in particular a DC link capacitor for a multi-phase system. The capacitor comprises a surface electrode and a further surface electrode, whereby a first capacitor structure is arranged between a first region of the surface electrode and a further first region of the further surface electrode, whereby the first capacitor structure is connected in an electrically conductive manner to the first region of the surface electrode and to the further first region of the further surface electrode, whereby the first region of the surface electrode is arranged on a base side of the capacitor and the further first region of the further surface electrode is arranged on an upper side of the capacitor facing away from the base side. According to the invention, a second capacitor structure is arranged between a second region of the surface electrode and a further second region of the further surface electrode, whereby the second capacitor structure is connected in an electrically conductive manner to the second region of the surface electrode and to the further second region of the further surface electrode, whereby the further second region of the further surface electrode is arranged on the base side of the capacitor and the second region of the surface electrode is arranged on the upper side of the capacitor, whereby a third capacitor structure is arranged between a third region of the surface electrode and a further third region of the further surface electrode, whereby the third capacitor structure is connected in an electrically conductive manner to the third region of the surface electrode and to the further third region of the further surface electrode, whereby the third region of the surface electrode is arranged on a base side of the capacitor and the further third region of the further surface electrode is arranged on the upper side of the capacitor.

Compared to the prior art, the capacitor having the features of the independent claim has the advantage that the capacitor can be well and evenly cooled in an advantageous manner. If the base side of the capacitor is arranged on a heat sink, then both surface electrodes of the capacitor are in close thermally conductive contact with the heat sink. The heat generated from both surface electrodes can thus be dissipated via only one side of the capacitor, specifically the base side of the capacitor. Even with only one heat sink on the base side of the capacitor, it is possible to ensure that none of the surface electrodes heats up too much. Both surface electrodes are cooled to the same extent via the base side. The capacitor can thereby be cooled particularly well and evenly with just one heat sink on the base side of the capacitor. A much more complex double-sided cooling of the capacitor in order to cool both surface electrodes is not necessary. Simultaneous cooling of the two surface electrodes thus reduces the overall heat dissipation effort for the capacitor. If the capacitor structures are heat-sensitive, the capacitor structures are protected from heat introduced via the surface electrodes and the associated damage. Therefore, more heat-sensitive capacitor structures can, e.g., also be used. Furthermore, heat loss in the surface electrodes, e.g. due to switching processes, is also dissipated via the heat sink arranged on the base side of the capacitor. The common cooling of both surface electrodes on the base side of the capacitor can also advantageously reduce the installation space required and the costs of the capacitor.

Furthermore, the first region of the surface electrode and the further second area of the further surface electrode and the third area of the surface electrode can together form a bearing surface, in particular a flat one, on which the capacitor can be arranged on the heat sink, e.g. with an insulating element placed between them. Therefore, both the surface electrode and the further surface electrode are connected to the heat sink in a thermally conductive manner and the capacitor can be cooled advantageously well and evenly. The first region of the surface electrode together with the third region of the surface electrode can have essentially the same area as the second region of the further surface electrode. Uniform cooling of the two surface electrodes can thus be achieved.

Furthermore, the capacitor can have a symmetrically identical design. The electrical symmetry is able to be maintained as a result. Thus, for example, two electrical and/or electronic units connected in parallel, such as power modules, can be connected symmetrically to the capacitor, which improves the stability of circuits due to feedback, e.g. in a gate control circuit, and the electromagnetic compatibility of the overall system.

Further advantageous embodiments and further developments of the invention are made possible by the features specified in the dependent claims.

According to an advantageous exemplary embodiment, it is provided that the second region of the surface electrode is arranged between the further first region of the further surface electrode and the further third region of the further surface electrode and the further second region of the further surface electrode is arranged between the first region of the surface electrode and the third region of the surface electrode.

According to an advantageous exemplary embodiment, it is provided that the first region of the surface electrode and the further second region of the further surface electrode and the third region of the surface electrode are arranged in a common ground level on the base side of the capacitor. The first region of the surface electrode and the further second region of the further surface electrode and the third region of the surface electrode can, e.g., extend over a large area in the common ground level. The heat can thus be dissipated evenly over a large area via the base side of the capacitor to the heat sink. An insulating layer insulating the surface electrodes from the heat sink can, e.g., be arranged between the heat sink and the capacitor.

According to an advantageous exemplary embodiment, it is provided that a first intermediate region of the surface electrode connects the first region of the surface electrode to the second region of the surface electrode and a further first intermediate region of the further surface electrode connects the further first region of the further surface electrode to the further second region of the further surface electrode, whereby the first intermediate region of the surface electrode and the further first intermediate region of the further surface electrode are arranged between the first capacitor structure and the second capacitor structure. The surface electrodes are guided through the first intermediate regions from the base side of the capacitor to the upper side of the capacitor. The surface electrodes extend between the first capacitor structure and the second capacitor structure.

According to an advantageous exemplary embodiment, it is provided that the first intermediate region and/or the further first intermediate region extend in a planar manner perpendicular to the first region of the surface electrode and to the further second region of the further surface electrode. The first intermediate regions can extend plane-parallel to each other. Due to the parallel guidance of the intermediate regions, a low-inductance structure of the capacitor can be achieved.

According to one advantageous exemplary embodiment, it is provided that a second intermediate region of the surface electrode connects the second region of the surface electrode to the third region of the surface electrode and a further second intermediate region of the further surface electrode connects the further second region of the further surface electrode to the further third region of the further surface electrode, whereby the second intermediate region of the surface electrode and the further second intermediate region of the further surface electrode are arranged between the second capacitor structure and the third capacitor structure.

According to an advantageous exemplary embodiment, it is provided that the second intermediate region and/or the further second intermediate region extend in a planar manner perpendicular to the further second region of the further surface electrode and to the third region of the surface electrode. The second intermediate regions can extend plane-parallel to each other. A very low-inductance connection along the capacitor can be achieved by running the intermediate regions in parallel.

According to an advantageous exemplary embodiment, the capacitor is designed to be symmetrically identical. An electrical symmetry can be created thereby. Therefore, two electrical and/or electronic units connected in parallel, such as power modules, can, e.g., be connected symmetrically to the capacitor, which improves the stability of circuits due to feedback, e.g. in a gate control circuit, and the electromagnetic compatibility of the overall system.

Further proposed is an assembly comprising a capacitor and a heat sink, whereby the base side of the capacitor lies flat on the heat sink. The base side of the capacitor can, e.g., lie on the heat sink with an intermediate insulating layer.

According to an advantageous exemplary embodiment, it is provided that the assembly further comprises at least one electrical and/or electronic unit, whereby the electrical and/or electronic unit is arranged on the heat sink for cooling.

### BRIEF DESCRIPTION OF THE DRAWINGS

An exemplary embodiment of the invention is shown in the drawings and explained in further detail in the subsequent description. Shown are:

FIG. 1 a cross-section through an exemplary embodiment of the capacitor,

FIG. 2 a cut-out view of the two surface electrodes of the capacitor from FIG. 1.

### DETAILED DESCRIPTION

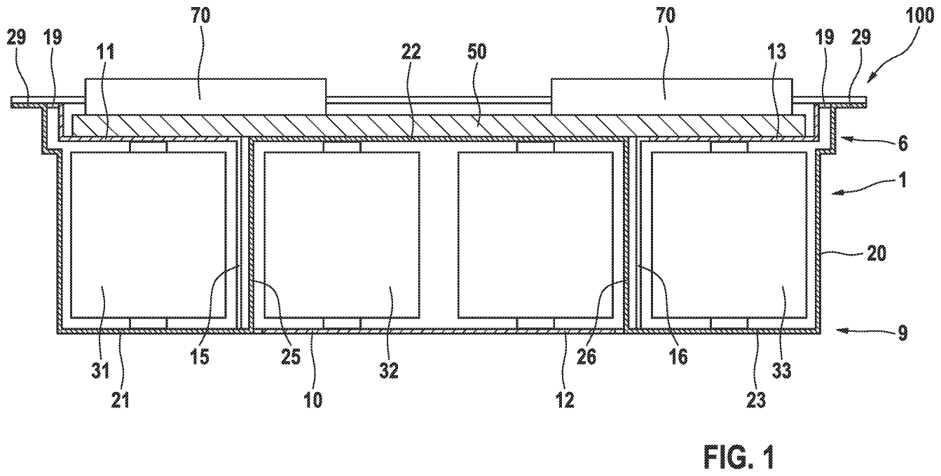

FIG. 1 shows a cross-section of an assembly 100 with a capacitor 1. The assembly 100 comprises the capacitor 1 and a heat sink 50. The assembly 100 further comprises an electrical and/or electronic unit 70.

The heat sink 50 is, e.g., made of a material with excellent thermal conductivity, e.g.

a metal, e.g. aluminum. A first bearing surface, in particular a flat one, is formed on the heat sink 50, on which the capacitor 1 is arranged and fastened A base side 6 of the capacitor 1 is in indirect or direct contact with the first bearing surface of the heat sink 50. The heat sink 50 further comprises a second bearing surface, in particular facing away from the first bearing surface, on which the electrical and/or electronic unit 70 is arranged. The electrical and/or electronic unit 70 can, e.g., be soldered to the heat sink 50. The first bearing surface is, e.g., arranged plane-parallel to the second bearing surface. The heat sink 50 is, e.g., designed as a plate.

Furthermore, the assembly 100 comprises at least one electrical and/or electronic unit 70. The electrical and/or electronic unit 70 can, e.g., form a power circuit, such as an inverter structure or a converter structure, e.g. of hybrid vehicles or electric vehicles. The electrical and/or electronic unit 70 can, e.g. be designed as a power module and, e.g., comprise a carrier substrate having traces on which, e.g., power semiconductors are arranged to form an electrical and/or electronic unit 70 together with the carrier substrate. The electrical and/or electronic unit 70 comprises a base surface. The base surface is, e.g., flat. The base surface can, e.g., be formed on an underside of a carrier substrate of the electrical and/or electronic unit 70. The base surface can, e.g., be made of copper. During operation, heat is generated by the electrical and/or electronic unit 70, which is dissipated to the heat sink 50. For this purpose, the electrical and/or electronic unit 70 is arranged on the heat sink 50, in particular on the second bearing surface of the heat sink 50. An intermediate layer for fastening and thermally connecting the electrical and/or electronic unit 70 to the heat sink 50 can, e.g., be arranged between the heat sink 50 and the electrical and/or electronic unit 70. The intermediate layer is, e.g., designed as a solder layer, in particular from a soft solder.

Furthermore, the assembly 100 comprises the capacitor 1. The capacitor 1 can, e.g., be designed as a DC link capacitor in an inverter. The capacitor 1 comprises a plurality of capacitor structures 31, 32, 33 and two surface electrodes 10, 20. Both surface electrodes 10, 20 are electrically connected to the capacitor structures 31, 32, 33. The capacitor structures 31, 32, 33 are, e.g., connected in parallel to each other via the two surface electrodes 10, 20. The two surface electrodes 10, 20 form electrodes via which the capacitor structures 31, 32, 33 are electrically interconnected. The surface electrodes 10, 20 are made of electrically conductive material, e.g. a metal such as copper. The surface electrodes 10, 20 are designed to be flat and can, e.g., be made of sheet metal. The capacitor structures 31, 32, 33 each comprise at least one dielectric. In the context of the present application, a capacitor structure 31, 32, 33 is understood to be a structure which, together with the surface electrode 10 and the further surface electrode 20, can form a capacitor 1, or which itself forms a capacitor. The capacitor structure 31, 32, 33 can, e.g., be a dielectric 2 so that the surface electrode 10 together with the further surface electrode 20 and the dielectric arranged between the surface electrode 10 and the further surface electrode 20 form a capacitor. However, the capacitor structure 31, 32, 33 can also comprise one or more capacitors arranged between the surface electrode 10 and the further surface electrode 20 and can be connected in parallel or in series, depending on the intended use. The capacitor structures 31, 32, 33 are each connected in an electrically conductive manner, e.g. welded, to both the first surface electrode 10 and the second surface electrode 20. Various capacitor technologies, e.g. stack, cylindrical, or flat-pack capacitors can be used as capacitors. These can, e.g., be in electrically conductive contact with the surface electrodes 10, 20.

The surface electrodes 10, 20 are designed to be flat. In principle, however, at least slight deviations from the flat shape are also possible for the surface electrodes 10, 20. The surface electrodes 10, 20 can, e.g., also be formed in several layers. Recesses not shown in the figures can also be formed in the surface electrodes 10,20, e.g. for welding to the capacitor elements 31, 32, 33. The surface electrodes 10,20 are, e.g., made of sheet metal. The surface electrodes 10, 20 are arranged parallel to each other in sections.

Furthermore, the capacitor 1 comprises at least one pole connection 19 for making electrical contact with the surface electrode 10 and at least one second pole connection 29 for making electrical contact with the further surface electrode 20. The pole connections 19, 29 are electrically contacted, e.g., with the electrical and/or electronic unit 70. The pole connection 19 is, e.g., designed to be integral with the surface electrode 10. The further pole connection 29 is, e.g., designed to be integral with the further surface electrode 20. The pole connection 19 extends in lateral continuation of the first surface electrode 10. The further pole connection 29 extends in lateral continuation of the further surface electrode 20. The pole connection 19 and the further pole connection 29 form, e.g., a pair of contacting lugs projecting from the base side 6 of the capacitor 1. In the exemplary embodiments shown, two pole connections 19 are provided on the surface electrode 10 and two further pole connections 29 are provided on the further surface electrode 20. The pole connections 19 of the surface electrode 10 and the further pole connections 29 of the further surface electrode 20 each form, e.g., a pair of contacting lugs. In the embodiments described in the present application, two pairs of contacting lugs are shown. In the exemplary embodiment, pairs of contacting lugs are arranged on sides of the capacitor 1 that face away from each other. In addition, however, a different number of contacting lug pairs can also be formed on the capacitor 1 and the contacting lug pairs can be arranged at other locations on the capacitor 1. In the exemplary embodiments, the pole connection 19 is arranged at least partially directly above or at least partially directly below the further pole connection 29. However, the pole connection 19 can, e.g., also be arranged laterally offset to the further pole connection 29. The pole connections 19, 29 can, e.g., be flat. The pole connection 19 and the further pole connection 29 have, e.g., the same surface area. Current can flow from the further pole connection 29 via the further surface electrode 20 to the capacitor structures 31, 32, 33 or current can flow in the opposite direction from the capacitor structures 31, 32, 33 via the further surface electrode 20 to the further pole connection 29. At the same time, current can flow from the pole connection 19 via the surface electrode 10 to the capacitor structures 31, 32, 33 or current can flow in the opposite direction from the capacitor structures 31, 32, 33 via the surface electrode 10 to the pole connection 19.

The surface electrode 10 has a first region 11 and the further surface electrode 20 has a further first region 21. First capacitor structures 31 are arranged between the first region 11 of the surface electrode 10 and the further first region 21 of the further surface electrode 20. The first capacitor structures 31 are each connected in an electrically conductive manner to the surface electrode 10 at the first region 11 of the surface electrode 10 and are each connected in an electrically conductive manner to the further surface electrode 20 at the further first region 21 of the further surface electrode 20. The first region 11 of the surface electrode 10 is arranged on a base side 6 of the capacitor 1 and the further first region 21 of the further surface electrode 20 is arranged on an upper side 9 of the capacitor 1 facing away from the base side 6. The first region 11 and the further first region 21 are each flat. The first region 11 of the surface electrode 10 and the further first region 21 of the further surface electrode 10 are arranged plane-parallel to each other. The first capacitor structures 31 are arranged between the upper side 9 of the capacitor 1 and the base side 6 of the capacitor 1.

The surface electrode 10 also has a second area 12. The further surface electrode 20 has a further first region 21 and a further second region 22. First capacitor structures 31 are arranged between the first region 11 of the surface electrode 10 and the further first region 21 of the further surface electrode 20. Second capacitor structures 32 are arranged between the second region 12 of the surface electrode 10 and the further second region 22 of the further surface electrode 20. The first capacitor structures 31 are each connected in an electrically conductive manner to the surface electrode 10 at the first region 11 of the surface electrode 10 and are each connected in an electrically conductive manner to the further surface electrode 20 at the further first region 21 of the further surface electrode 20. The second capacitor structures 32 are each connected in an electrically conductive manner to the surface electrode 10 at the second region 12 of the surface electrode 10 and are each connected in an electrically conductive manner to the further surface electrode 20 at the further second region 22 of the further surface electrode 20.

The first region 11 of the surface electrode 10 is arranged on the base side 6 of the capacitor 1. The second region 12 of the surface electrode 10 is arranged on the upper side 9 of the capacitor 1. The first region 11 of the surface electrode 10 extends plane-parallel to the second region 12 of the surface electrode 10. The first region 11 of the surface electrode 10 is connected to the second region 12 of the surface electrode 10 by a first intermediate region 15 of the surface electrode 10 The first intermediate region 15 extends between the base side 6 and the upper side 9 of the capacitor 1. The surface electrode 10 is angled between the first region 11 and the first intermediate region 15, in particular by 90 degrees. The surface electrode 10 is angled between the first intermediate region 15 and the second region 12, in particular by 90 degrees. The first intermediate region 15 extends perpendicular to the first region 11 and/or perpendicular to the second region 12. The first intermediate region 15 is arranged between the first capacitor structures 31 and the second capacitor structures 32.

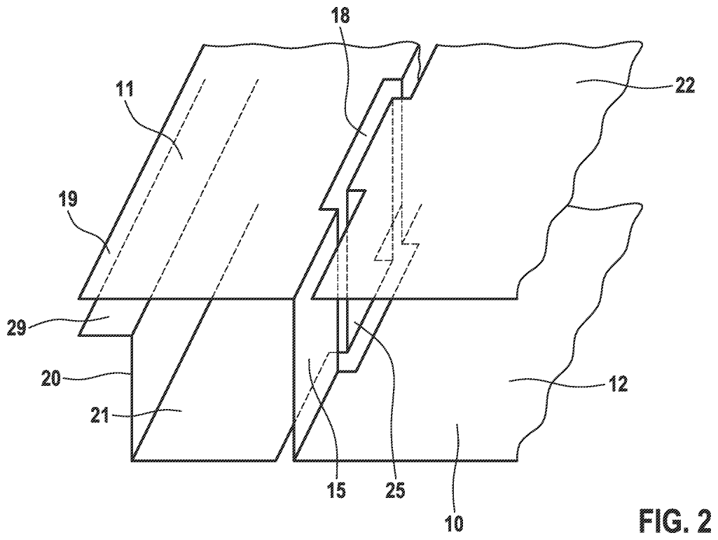

The further first region 21 of the further surface electrode 20 is arranged on the upper side 9 of the capacitor 1. The further second region 22 of the further surface electrode 20 is arranged on the base side 6 of the capacitor 1. The further first region 21 of the further surface electrode 20 extends plane-parallel to the further second region 22 of the further surface electrode 20. The further first region 21 of the further surface electrode 20 is connected to the further second region 22 of the further surface electrode 20 by a further first intermediate region 25 of the further surface electrode 20. The further first intermediate region 25 extends between the base side 6 and the upper side 9 of the capacitor 1. The further surface electrode 20 is angled between the further first region 21 and the further first intermediate region 25, in particular by 90 degrees. The further surface electrode 20 is angled between the further first intermediate region 25 and the further second region 22, in particular by 90 degrees. The further first intermediate region 25 extends perpendicularly to the further first region 21 and/or perpendicularly to the further second region 22. The further first intermediate region 25 is arranged between the first capacitor structures 31 and the second capacitor structures 32. The first intermediate region 15 of the surface electrode 10 and the further first intermediate region 25 of the further surface electrode 20 are arranged at least partially plane-parallel to each other. In the region between the first capacitor elements 31 and the second capacitor elements 32, the surface electrode 10 and the further surface electrode 20 intersect. As shown in FIG. 2, a recess 18 can, e.g., be formed in the surface electrode 10, through which the further surface electrode 20 passes. Furthermore, a recess can, e.g., be formed in the further surface electrode 20, through which the surface electrode 10 passes. In particular, the recess can be formed in the region of the first intermediate region 15 or in the region of the further first intermediate region 25.

Furthermore, the capacitor 1 comprises a third capacitor element 33, a third region 13 is formed on the surface electrode 10 and a further third region 23 is formed on the further surface electrode 20. A third capacitor structure 33 is arranged between the third region 13 of the surface electrode 10 and the further third region 23 of the further surface electrode 20. The third capacitor structure 33 is connected in an electrically conductive manner at the third region 13 of the surface electrode 10 to the surface electrode 10 and is connected in an electrically conductive manner at the further third region 23 of the further surface electrode 20 to the further surface electrode 20. The third region 13 of the surface electrode 10 is arranged on the base side 6 of the capacitor 1. The third region 13 of the surface electrode 10 extends plane-parallel to the second region 12 of the surface electrode 10. The third region 13 of the surface electrode 10 is connected to the second region 12 of the surface electrode 10 by a second intermediate region 16 of the surface electrode 10. The second intermediate region 16 extends between the base side 6 and the upper side 9 of the capacitor 1. The surface electrode 10 is angled between the second region 12 and the second intermediate region 16, in particular by 90 degrees. The surface electrode 10 is angled between the second intermediate region 16 and the third region 13, in particular by 90 degrees. The second intermediate region 16 extends perpendicular to the second region 12 and/or perpendicular to the third region 13. The second intermediate region 16 is arranged between the second capacitor structure 32 and the third capacitor structure 33.

The further third region 23 of the further surface electrode 20 is arranged on the upper side 9 of the capacitor 1. The further third region 23 of the further surface electrode 20 extends plane-parallel to the further second region 22 of the further surface electrode 20. The further third region 23 of the further surface electrode 20 is connected to the further second region 22 of the further surface electrode 20 by a further second intermediate region 26 of the further surface electrode 20. The further second intermediate region 26 extends between the base side 6 and the upper side 9 of the capacitor 1. The further surface electrode 20 is angled between the further second region 22 and the further second intermediate region 26, in particular by 90 degrees. The further surface electrode 20 is angled between the further second intermediate region 26 and the further third region 23, in particular by 90 degrees. The further second intermediate region 26 extends perpendicular to the further third region 23 and/or perpendicular to the further second region 22. The further second intermediate region 26 is arranged between the second capacitor structure 32 and the third capacitor structure 33. The second intermediate region 16 of the surface electrode 10 and the further second intermediate region 26 of the further surface electrode 20 are arranged at least partially plane-parallel to each other. In the region between the second capacitor element 32 and the third capacitor element 33, the surface electrode 10 and the further surface electrode 20 cross each other. For example, in the region of the second intermediate regions 16, 26, a recess can be formed in one of the surface electrodes 10, 20, in which one of the surface electrodes 10, 20 passes through the further surface electrode 10, 20. The second capacitor element 32 is arranged between the first intermediate region 15 and the second intermediate region 16 of the surface electrode 10. The surface electrode 10, in particular the first intermediate region 15 and the second region 12 and the second intermediate region 16 of the surface electrode 10, encircle the second capacitor element 32 in a U-shape. The further surface electrode 20, in particular the further first intermediate region 25 and the further second region 22 and the second intermediate region 26 of the further surface electrode 20, encircle the second capacitor element 32 in a U-shape. In the second exemplary embodiment, the capacitor 1 has a symmetrically identical design. In this exemplary embodiment, the first region 11 of the surface electrode 10 and the further second region 22 of the further surface electrode 20 and the third region 13 of the surface electrode 10 are arranged in a common ground level on the base side 6 of the capacitor 1. Furthermore, in this exemplary embodiment, the second region 12 of the surface electrode 10 and the further first region 21 of the further surface electrode 20 and the further third region 23 of the further surface electrode 20 are arranged in a common upper side plane on the upper side 9 of the capacitor 1.

Of course, further exemplary embodiments and mixed forms of the illustrated exemplary embodiments are also possible.

1. A capacitor (1) comprising a surface electrode (10) and a further surface electrode (20), wherein a first capacitor structure (31) is arranged between a first region (11) of the surface electrode (10) and a further first region (21) of the further surface electrode (20), wherein the first capacitor structure (31) is connected in an electrically conductive manner to the first region (11) of the surface electrode (10) and to the further first region (21) of the further surface electrode (20), wherein the first region (11) of the surface electrode (10) is arranged on a base side (6) of the capacitor (1) and the further first region (21) of the further surface electrode (20) is arranged on an upper side (9) of the capacitor (1) facing away from the base side (6),
wherein a second capacitor structure (32) is arranged between a second region (12) of the surface electrode (10) and a further second region (22) of the further surface electrode (20), wherein the second capacitor structure (32) is connected in an electrically conductive manner to the second region (12) of the surface electrode (10) and the further second region (22) of the further surface electrode (20), wherein the further second region (22) of the further surface electrode (20) is arranged on the base side (6) of the capacitor (1) and the second region (12) of the surface electrode (10) is arranged on the upper side (9) of the capacitor (1), wherein a third capacitor structure (33) is arranged between a third region (13) of the surface electrode (10) and a further third region (23) of the further surface electrode (20), wherein the third capacitor structure (33) is connected in an electrically conductive manner to the third region (13) of the surface electrode (10) and to the further third region (23) of the further surface electrode (20), wherein the third region (13) of the surface electrode (10) is arranged on a base side (6) of the capacitor (1) and the further third region (23) of the further surface electrode (20) is arranged on the upper side (9) of the capacitor (1).

2. The capacitor according to claim 1, wherein the second region (12) of the surface electrode (10) is arranged between the further first region (21) of the further surface electrode (20) and the further third region (23) of the further surface electrode (20), and the further second region (22) of the further surface electrode (20) is arranged between the first region (11) of the surface electrode (10) and the third region (13) of the surface electrode (10).

3. The capacitor according to claim 1, wherein the first region (11) of the surface electrode (10) and the further second region (22) of the further surface electrode (20) and the third region (13) of the surface electrode (10) are arranged in a common ground level on the base side (6) of the capacitor (1).

4. The capacitor according to claim 1, wherein a first intermediate region (15) of the surface electrode (10) connects the first region (11) of the surface electrode (10) to the second region (12) of the surface electrode (10) and a further first intermediate region (25) of the further surface electrode (20) connects the further first region (21) of the further surface electrode (20) to the further second region (22) of the further surface electrode (20), wherein the first intermediate region (15) of the surface electrode (10) and the further first intermediate region (25) of the further surface electrode (20) are arranged between the first capacitor structure (31) and the second capacitor structure (32).

5. The capacitor according to claim 4, wherein the first intermediate region (15) and/or the further first intermediate region (25) extend in a planar manner perpendicular to the first region (11) of the surface electrode (10) and to the further second region (22) of the further surface electrode (20).

6. The capacitor according to claim 1, wherein a second intermediate region (16) of the surface electrode (10) connects the second region (12) of the surface electrode (10) to the third region (13) of the surface electrode (10), and a further second intermediate region (26) of the further surface electrode (20) connects the further second region (22) of the further surface electrode (20) to the further third region (23) of the further surface electrode (20), wherein the second intermediate region (16) of the surface electrode (10) and the further second intermediate region (26) of the further surface electrode (20) are arranged between the second capacitor structure (32) and the third capacitor structure (33).

7. The capacitor according to claim 6, wherein the second intermediate region (16) and/or the further second intermediate region (26) extend in a planar manner perpendicular to the further second region (22) of the further surface electrode (20) and to the third region (13) of the surface electrode (10).

8. The capacitor according to claim 1, wherein the capacitor (1) is designed to be symmetrically identical.

9. An assembly comprising a capacitor (1) that includes a surface electrode (10) and a further surface electrode (20), wherein a first capacitor structure (31) is arranged between a first region (11) of the surface electrode (10) and a further first region (21) of the further surface electrode (20), wherein the first capacitor structure (31) is connected in an electrically conductive manner to the first region (11) of the surface electrode (10) and to the further first region (21) of the further surface electrode (20), wherein the first region (11) of the surface electrode (10) is arranged on a base side (6) of the capacitor (1) and the further first region (21) of the further surface electrode (20) is arranged on an upper side (9) of the capacitor (1) facing away from the base side (6),
wherein a second capacitor structure (32) is arranged between a second region (12) of the surface electrode (10) and a further second region (22) of the further surface electrode (20), wherein the second capacitor structure (32) is connected in an electrically conductive manner to the second region (12) of the surface electrode (10) and the further second region (22) of the further surface electrode (20), wherein the further second region (22) of the further surface electrode (20) is arranged on the base side (6) of the capacitor (1) and the second region (12) of the surface electrode (10) is arranged on the upper side (9) of the capacitor (1), wherein a third capacitor structure (33) is arranged between a third region (13) of the surface electrode (10) and a further third region (23) of the further surface electrode (20), wherein the third capacitor structure (33) is connected in an electrically conductive manner to the third region (13) of the surface electrode (10) and to the further third region (23) of the further surface electrode (20), wherein the third region (13) of the surface electrode (10) is arranged on a base side (6) of the capacitor (1) and the further third region (23) of the further surface electrode (20) is arranged on the upper side (9) of the capacitor (1), and
a heat sink (50), wherein the base side (6) of the capacitor (1) rests flat on the heat sink (50

10. The assembly according to claim 9, wherein the assembly (100) further comprises at least one electrical and/or electronic unit (70), wherein the electrical and/or electronic unit (70) is arranged on the heat sink (50) for cooling.
